(19) United States
(12) Patent Application Publication
(10) Pub. No.: US 2011/0260210 A1
(43) Pub. Date: Oct. 27, 2011

(54) GAN-BASED LEDS ON SILICON SUBSTRATES WITH MONOLITHICALLY INTEGRATED ZENER DIODES

(75) Inventor: Jie SU, Santa Clara, CA (US)

(73) Assignee: Applied Materials, Inc., Santa Clara, CA (US)

(21) Appl. No.: 13/045,354

(22) Filed: Mar. 10, 2011

Related U.S. Application Data
(60) Provisional application No. 61/327,459, filed on Apr. 23, 2010.

(51) Int. Cl. H01L 33/32; C23C 16/34; C23C 16/24; C23C 16/44; C23C 16/455

(52) U.S. Cl. 257/103; 438/23; 118/719; 257/E33.023

(57) ABSTRACT

Monolithically integrated GaN LEDs with silicon-based ESD protection diodes. Hybrid MOCVD or HVPE epitaxial systems may be utilized for in-situ epitaxially growth of doped silicon containing films to form both the silicon-based ESD protection diode material stacks as well as a silicon containing transition layer prior to growth of a GaN-based LED material stack. The silicon-based ESD protection diodes may be interconnected with layers of a GaN LED material stack to form Zener diodes connected with the GaN LEDs.

### CROSS-REFERENCE TO RELATED APPLICATIONS

This application claims the benefit of U.S. Provisional Application No. 61/327,459 filed on Apr. 23, 2010, entitled “GAN BASED LEDS ON SI WITH MONOLITHICALLY INTEGRATED ESD PROTECTION ZENER DIODES,” the entire contents of which are hereby incorporated by reference herein.

### BACKGROUND

1. Field

Embodiments of the present invention pertain to the field of group III-nitride thin film epitaxy and, in particular, to monolithic integration of GaN thin film structures with silicon-based ESD protection diode structures.

2. Description of Related Art

Group III-nitride materials are playing an ever increasing role in semiconductor devices (e.g., power electronics and light-emitting diodes (LEDs). Many such devices rely on an epitaxial growth of group III-nitride films, such as gallium nitride (GaN). Electrostatic discharge (ESD) induced electrical pulses are a major reliability concern because many GaN-based diodes are particularly prone to ESD (e.g., reverse discharges). This sensitivity has motivated the development of ESD protection circuits or GaN-based devices. Typically, these ESD protection circuits include a series of silicon diodes or one or more silicon Zener diodes. During reverse discharges, the high current of the electric pulse bypasses the device (e.g., LED) and flows through the protection diodes.

Usually, ESD protection circuits have been integrated with external silicon submounts (see e.g., Stegerwald et al. in IEEE J. Sel. Top. Quantum Electron, 8, 310 (2002). Others have proposed a Schottky diode integrated with the LED on the same chip Other conventional protection diode structures include GaN-based p-n junctions.

### BRIEF DESCRIPTION OF THE DRAWINGS

Embodiments of the present invention are illustrated by way of example, and not by way of limitation, in the figures of the accompanying drawings, in which:

FIG. 1A is a flow diagram illustrating a method for forming a monolithic ESD protected GaN-based LED diode stack including a doped silicon-containing layer disposed over a silicon substrate and a GaN-based LED stack disposed over the doped silicon-containing layer, in accordance with an embodiment of the present invention;

FIG. 1B illustrates a cross-sectional diagram of a GaN LED material stack disposed over a silicon-based diode material stack electrically coupled to form a silicon-based Zener diode providing ESD protection to a GaN-based LED, in accordance with an embodiment of a monolithic ESD protected GaN-based LED;

FIG. 1C illustrates a schematic of the monolithic ESD protected GaN-based LED depicted in FIG. 1B;

FIG. 1D illustrates a cross-sectional diagram of a GaN LED material stack disposed over a silicon-based diode material stack electrically coupled to form a silicon-based Zener diode providing ESD protection to a GaN-based LED, in accordance with an embodiment of a monolithic ESD protected GaN-based LED;

FIG. 1E illustrates a schematic of the monolithic ESD protected GaN-based LED depicted in FIG. 1D;

FIG. 1F illustrates a cross-sectional diagram of a GaN LED material stack disposed over a silicon-based diode material stack electrically coupled to form a silicon-based Zener diode pair providing ESD protection to a GaN-based LED, in accordance with an embodiment of a monolithic ESD protected GaN-based LED;

FIG. 1G illustrates a schematic of the monolithic ESD protected GaN-based LED depicted in FIG. 1F;

FIG. 2 is a schematic cross-sectional view of a hybrid MOCVD chamber configured to grow both a doped silicon diode layer and a GaN LED device layer, in accordance with an embodiment of the present invention;

FIG. 3 is a schematic view of an HVPE apparatus configured to grow both a doped silicon diode layer and a GaN LED device layer, in accordance with an embodiment of the present invention;

FIG. 4 is a schematic plan view of a multi-chambered epitaxy system including a plurality of chambers, each chamber configured to grow both a doped silicon diode layer and a GaN LED device layer, in accordance with an embodiment of the present invention; and

FIG. 5 is a schematic of a computer system, in accordance with an embodiment of the present invention.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the phrase “in an embodiment” in various places throughout this specification is not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

The terms “over,” “under,” “between,” and “on” as used herein refer to a relative position of one material layer with respect to other layers. As such, for example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in contact with that second layer. Additionally, the relative position of one layer with respect to other layers is provided assuming operations are performed relative to a substrate without consideration of the absolute orientation of the substrate.

Embodiments of GaN devices monolithically integrated with silicon-based ESD protection diodes are described herein. Growth of GaN-based devices on silicon substrates is utilized to monolithically integrate silicon-based ESD protection diodes with the device. This monolithic integration offers several advantages. First, for LED devices, the number of connections to external circuitry (e.g., submount) is reduced allowing light to be extracted from more area of the LED devices. Second, more compact packaging of the LED device dies may be accomplished. Also, monolithic serial arrays of LEDs with Zener diodes may be configured to operate at higher voltages than an individual LED, allowing for simplified power supply design.

As described further herein, the growth of silicon-containing device layers, such as p-type or n-type doped silicon layers may be performed as an operation in provisioning a silicon substrate upon which a GaN-based LED material stack is then grown. Alternatively, the growth of the silicon-containing device layers may be integrated with the growth of the LED material stack such that both silicon-based diode material layers and GaN-based LED material layers are grown successively upon a silicon substrate without breaking vacuum. For such embodiments, the silicon-based diode material layers may be grown either before or after growth of a silicon-based transition (buffer) layer disposed between the GaN-based LED material stack and the silicon substrate. For example, in the growth of the silicon-based transition layer (e.g., compositionally graded SiGe layer), an initial portion of the transition layer may be doped appropriately to form a silicon p-n junction with the silicon substrate. Alternatively, a final portion of the transition layer (e.g., compositionally graded SiGe layer) may be doped to form a SiGe p-n junction from which an ESD protection diode may be subsequently formed.

In further embodiments where the silicon-based device layer growth is in succession with the GaN-based LED device layer growth, a single hybrid deposition chamber may be utilized for both the silicon and GaN-based device layers to form a monolithically integrated ESD protection diode with a GaN-based LED without growth interruption. In such exemplary embodiments of the present invention, heteroepitaxial growth of doped silicon-containing layers are performed in-situ with group III-nitride films, such as GaN. As used herein, “in-situ” entails growing of both the doped silicon layers of the silicon-based ESD protection diode and group-III nitride layers of a GaN-based LED without interruption and without cycling the substrate temperature below that of the lowest deposition temperature between growths of the separate film layers. For example, in an in-situ growth of a GaN-based LED, after growth of a doped silicon layer (e.g., p-type silicon or p-type silicon germanium), vacuum is not broken and the substrate is not cooled to a temperature below the silicon deposition temperature prior to deposition of a silicon alloy transition layer (e.g., compositionally graded SiGe layer) and deposition of a group III-nitride LED stack (e.g., GaN-based LED material stack). Of course, multiple separate growth chambers (e.g., on a common platform under constant vacuum or on separate platforms with intervening vacuum breaks) may also be utilized to form the structures described herein however temperature cycling will typically occur for such embodiments.

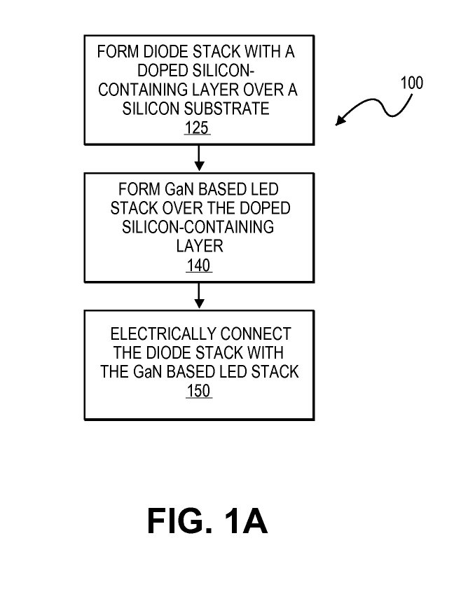

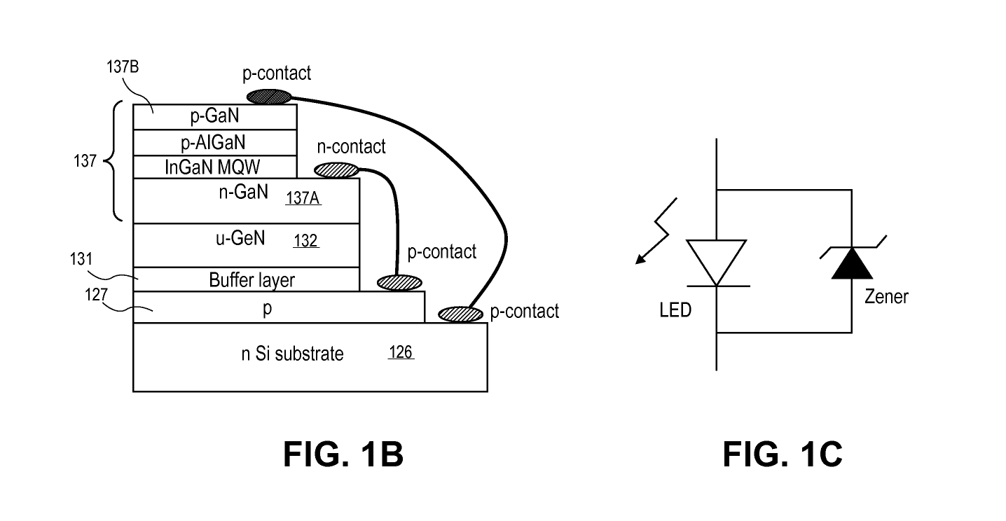

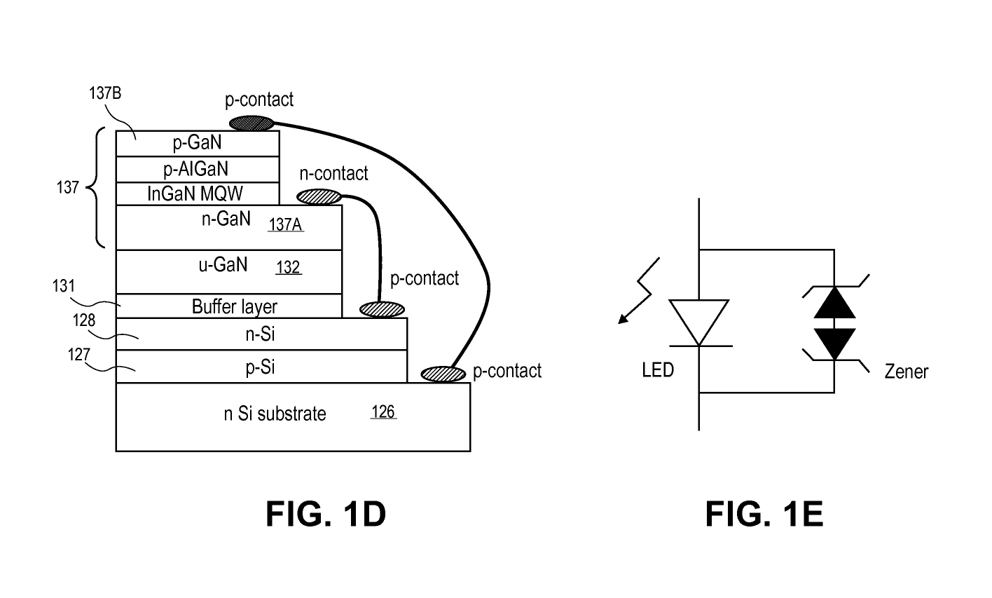

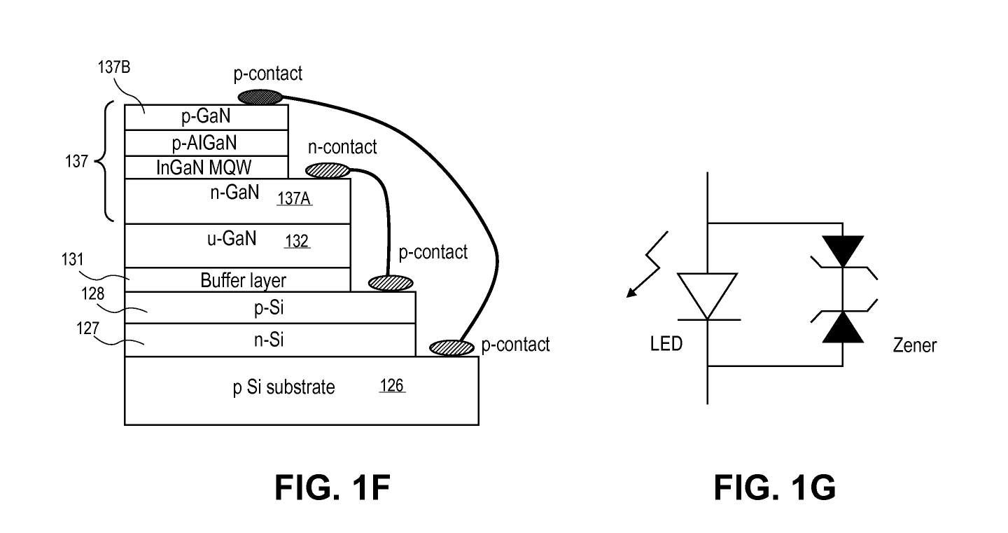

In an embodiment, fabricating a monolithic ESD protected group III-nitride based devicee includes forming a diode material stack including a doped silicon-based layer over a silicon substrate; forming a group III-nitride device material stack over the doped silicon-based layer; and electrically connecting a diode delineated from the diode stack with an LED, transistor, or other device delineated from the group III-nitride stack. As an exemplary embodiment, FIG. 1A illustrates a method 100 forming a monolithic ESD protected GaN-based LED. FIGS. 1B-1F illustrate exemplary embodiments of monolithic ESD protected GaN-based LEDs which may be formed by practicing method 100.

In FIG. 1A, the method 100 begins with forming a diode material stack including a doped silicon layer over a silicon substrate at operation 125. In the exemplary embodiments illustrated in FIGS. 1B, 1D and 1F, the substrate is a silicon substrate 126. The silicon substrate 126 may be any bulk or epitaxial single crystalline silicon having a crystallographic orientation of (111), (100) and (110). In a further embodiment, the silicon substrate 126 has an “off-cut” crystallographic orientation whereby the growth surface is 2-3° off of the major crystal axis to present a higher order plane as the growth surface. In embodiments, at least a top portion of the silicon substrate 126 is doped with an impurity to serve as a first side of a p-n junction. For the embodiments illustrated in FIGS. 1B and 1D, the silicon substrate 126 is doped with n-type impurity, such as phosphorus or arsenic. In alternative embodiments, as illustrated in FIG. 1C, the silicon substrate 126 is doped with a p-type impurity, such as boron.

FIGS. 1B, 1D and 1F further illustrate a first doped silicon-containing layer 127 formed over the silicon substrate 126. The doped silicon-containing layer 127 contains silicon which may be further alloyed with one or more other group IV constituents, such as germanium or carbon. In the exemplary embodiment, the doped silicon-containing layer 127 is not alloyed with any other group IV constituents (i.e., the doped silicon-containing layer 127 is intrinsic silicon). The doped silicon-containing layer 127 is further doped with a group III or group V impurity, to have an n-type or p-type conductivity and form a p-n junction with the silicon substrate 126. As illustrated in FIG. 1B, the doped silicon-containing layer 127 is doped p-type to form a p-n junction with the substrate silicon 126 doped n-type. As illustrated in FIG. 1F, the doped silicon-containing layer 127 is doped n-type to form a p-n junction with the silicon substrate 126 (doped p-type).

In embodiments, the silicon-based diode material stack includes a plurality of doped silicon-containing layers to form a plurality of p-n junctions. FIGS. 1D and 1F illustrate exemplary embodiments where the diode material stack further comprises a second doped silicon-containing layer 128 disposed over the first doped silicon-containing layer 127, the second doped silicon-containing layer 128 being of a conductivity type complementary to that of the first doped silicon-containing layer 127 to form a second p-n junction as part of the diode material stack. With the n-p-n silicon layers depicted in FIG. 1D and the p-n-p doped silicon layers depicted in FIG. 1F, a number of ESD protection diode configurations may be provided, as further illustrated in the schematics of FIGS. 1E and 1G. Similarly, three, four, or more p-n junctions may be formed over the silicon substrate 126 to provide for more complex ESD protection diode configurations, if desired.

As further illustrated in the structures depicted in FIGS. 1B, 1D, and 1F, a transition (buffer) layer 131 may be provided between the silicon substrate 126 and a GaN-based LED material stack 137. Generally, one or more of the doped silicon-containing layers making up the silicon-based diode material stack may disposed either above or below the transition layer 131. One or more of the doped silicon-containing layers making up the silicon-based diode material stack may also form a part of the transition layer 131. For example, in the exemplary embodiments depicted in FIGS. 1B, 1D and 1F, a silicon alloy epitaxial layer is grown as a transition layer 131. The silicon alloy may be grown as a compositionally graded alloy or to have a superlattice structure. The constituents of the silicon alloy include silicon and any of germanium (Ge), carbon (C), and tin (Sn). In particular embodiments the silicon alloy is a binary alloy, but in alternative embodiments, ternary alloys (e.g., SiC:Ge) may also be formed with impurity dopants (e.g., boron, nitrogen etc.) further be provided at low to moderate concentrations in the alloy matrix. In preferred embodiments the transition layer 131 is silicon germanium (SiGe) which may be compositionally graded or form a superlattice to satisfy thermal expansion and lattice matching functions, as known in the art. The first doped silicon-containing layer 127 may therefore be formed as a first portion of the transition layer 131 where the concentration of Ge is zero or very small to provide a silicon diode stack having a commensurate band gap and doping such that a reverse breakdown voltage is between about 5 and 6 volts and in particular embodiments, approximately 5.6 volts.

In further embodiments, a minor layer (not depicted) is disposed between the doped silicon-containing layer (127 or 128) and the transition layer 131. The minor layer is to reflect emitted light away from the substrate and prevent the light absorption by the silicon substrate 126. Typically, the mirror layer is a DBR structure (such as a ¼ wavelength multi-layered SiO₂/Si stack) or metallic reflective layer. Depending on whether the doped silicon-containing layer is formed as part of the substrate provisioning or as part of the LED material stack formation, the mirror layer may be formed in-situ or ex-situ with either the growth of the doped silicon-containing layer and/or the growth of the transition layer 131.

Returning to FIG. 1A, with the silicon-based diode material stack formed, the method 100 proceeds at operation 140 with formation of a GaN-based LED material stack. Generally, the GaN-based LED material stack may include binary alloys, ternary alloys (e.g., AlGaN) and higher. Additionally, impurity dopants (e.g., silicon, magnesium, etc.) may be provided at low to moderate concentrations in the alloy matrix. FIGS. 1B, 1D, and 1F, depict an exemplary GaN-based LED material stack 137. As illustrated, the GaN-based LED material stack 137 is formed over the transition layer 131. In particular embodiments, growth of the GaN-based LED material stack 137 (e.g., at operation 140) is preceded by deposition of a nucleation layer (not depicted) and an undoped GaN layer 132. The nucleation layer may be any known in the art for growth of GaN films, such as but not limited to aluminum nitride (AlN), graded AlₓGa₁₋ₓN, or AlₓGa₁₋ₓN/GaN superlattice. The GaN-based LED material stack 137 includes a p-type and n-type GaN layers and an intervening multiple quantum well (MQW) structure. Any GaN-based LED material stacks known in the art may also be formed, including for example, a plurality of MQW structures, tunneling layers, etc.

In certain embodiments, the GaN-based LED material stack 137 is grown at operation 140 without cycling the temperature of the substrate down below the growth temperature employed at operation 125. Generally, the GaN-based LED material stack 137 growth temperature will be higher than that of the doped silicon containing layer 127 and/or the transition layer 131 and therefore where both growth operations 125 and 140 are performed in a same epitaxial chamber, an in-situ growth process may proceed with a ramp in temperature after termination of the transition layer growth (or during a last portion of that growth) and either prior to growth of the GaN-based LED material stack 137 or during an initial portion of that growth (or nucleation layer growth). For such an in-situ growth of both silicon-based layers and GaN-based layers, the monolithic material stacks depicted in FIG. 1B, 1D and 1F are made without interruption. In-situ growths may, for example, eliminate the need for surface passivation or cleaning steps in between layer growths to avoid any native oxide layer or foreign impurities which could occur during the growth interruption if they are done in different chambers. Thermal cycling during substrate transfer may also be avoided to improve thermal budget for group III-nitride device structures.

In other embodiments however, the operations 125 and 140 of FIG. 1A are performed in separate epitaxial chambers which are either on a common platform such that there is no vacuum break between the growths of the silicon-based layers and GaN-based layers or on separate platforms with vacuum breaks between the growth of silicon-based layers and GaN-based layers.

Returning to FIG. 1A, at operation 150 the silicon-based diode material stack and the GaN-based LED material stack are delineated and electrically coupled together to form a monolithic ESD protected LED device. Generally, the material stacks may be delineated with any practice conventional in the art of microelectronic fabrication, such as lithographic patterning and physical/chemical etching. Once delineated, conventional metal interconnect techniques may be utilized to electrically connect one or more silicon-based diode layers with one or more GaN-based LED layers to achieve the interconnects illustrated as bond wires merely for explanatory propose in FIGS. 1B, 1D and 1F. The schematics illustrated in FIGS. 1C, 1E, and 1G depict exemplary electrical connection configurations of a silicon-based diode monolithically integrated with a GaN-based LED. Most ESD protection diode circuitry provided in discrete or submount designs may be provided monolithically through extension of the exemplary embodiments illustrated. For example, the connection between a doped GaN-based layer (e.g., n-type layer 137A) and doped silicon-containing layer (e.g., 127 or 128) may be provided with a metal layer contact deposited on the side-wall of a trench or mesa.

FIGS. 1B and 1C illustrate a general configuration in which a silicon-based ESD protection diode is electrically connected in parallel with a GaN-based LED. More specifically, a layer of the silicon-based ESD protection diode having a first conductivity type (e.g., p-type doped silicon-containing layer 127) is coupled with a layer of the GaN-based LED having a second conductivity type, complementary to the first (e.g., n-type doped GaN layer 137A), to operate the silicon-based diode in breakdown or Zener mode which will shunt ESD away from the GaN-based LED. As further illustrated in FIGS. 1D, the second doped silicon-containing layer 128 is electrically coupled to form a pair of Zener diodes with anode-to-anode configuration (p-type GaN layer 137B interconnected to n-type doped silicon substrate 126 and n-type GaN layer 137A interconnected to n-type second doped silicon-containing layer 128) to provide ESD protection to the GaN-based LED as depicted in FIG. 1E. Similarly, at operation 150, the p-n-p doped silicon (substrate 126 and layers 127, 128) may be electrically interconnected to form a pair of Zener diodes with the cathode-to-cathode configuration (p-type GaN layer 137B interconnected to p-type doped silicon substrate 126 and n-type GaN layer 137A interconnected to p-type second doped silicon-containing layer 128) to provided ESD protection to the GaN-based LED as depicted in FIG. 1E. The GaN-based LED may then be protected from both forward and reverse bias current extremes with voltage limits tailored by the band gap of the silicon-based diode material stack and/or multiplicity of serially configured diodes provided by the silicon-based diode material stack.

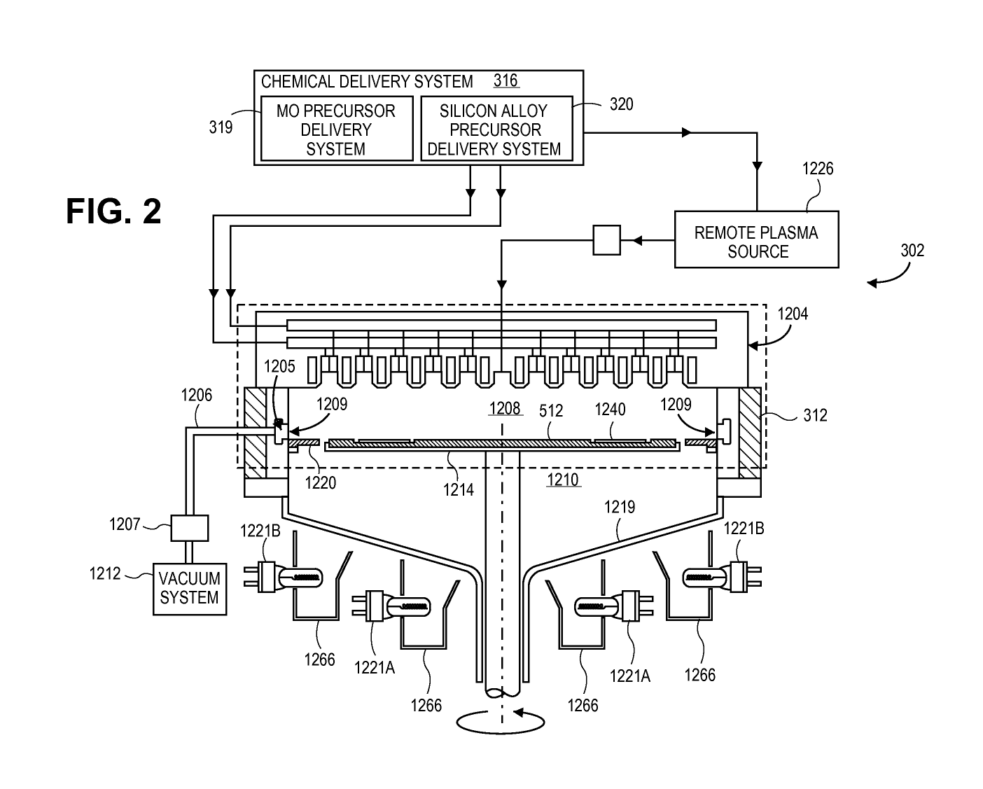

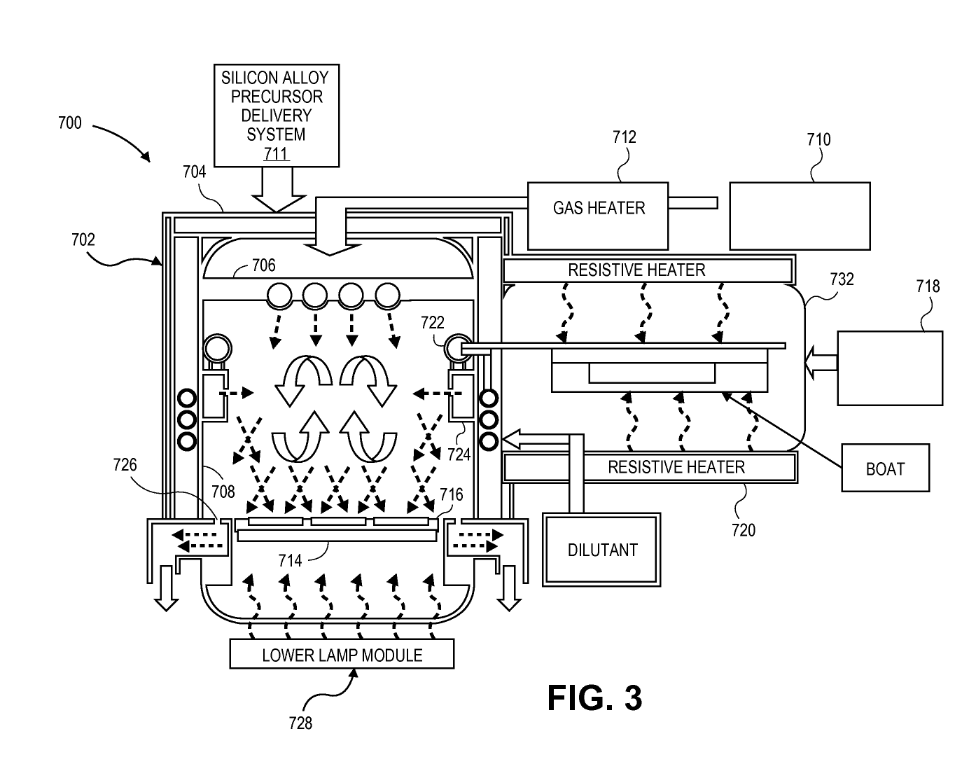

In certain in-situ growth embodiments, the silicon-based diode layers described in reference to FIGS. 1A-1F may be grown by either of the hybrid epitaxy chambers depicted in FIGS. 2 and 3. FIG. 2 is a schematic cross-sectional view of a hybrid MOCVD chamber which can be utilized in embodiments of the invention. The hybrid MOCVD chamber 302 comprises a chamber body 312, a chemical delivery module 316, a remote plasma source 1226, a substrate support 1214, and a vacuum system 1212. For the hybrid MOCVD chamber 302, the chemical delivery module 316 supplies chemicals to the hybrid MOCVD chamber 302 to perform both MOCVD with metalorganic precursor for group III-nitride film growth and CVD with non-metalorganic precursors for silicon-based film growth. Thus, the chemical delivery module 316 includes both a precursor delivery system 320 configured to be coupled to a silicon precursor source, a silicon alloy precursor source, if desired. One or more n-type or p-type dopants (e.g,. boron, arsenic, phosphorus, etc.) may be further provided to the hybrid MOCVD chamber 302 for doping of silicon-based diode stack materials as they are grown. Alternatively, such doping may be provided ex-situ of the silicon layer growths, for example by species implantation.

In particular embodiments, the precursor delivery system 320 is configured to provide a silicon precursor to the hybrid MOCVD chamber 302 for the doped silicon layer growths and provide a germanium precursor for the transition layer growths. The precursor delivery system 320 may be further configured to provide other reactive gases to form alternate alloys of silicon, such as carbon (C) or tin (Sn). In further embodiments, the precursor delivery system 320 is configured to provide oxidizers, such as O₂, ozone, etc., to facilitate deposition of silicon-containing non-crystalline compounds (e.g., SiO₂, Si3N₄). In certain such embodiments, the precursor delivery system 320 provides silica precursors (e.g., TEOS or others known in the art) to the hybrid MOCVD chamber 302. A second precursor delivery system 319 is configured to be coupled to a metalorganic precursor source. A second precursor delivery system 319 is configured to be coupled to a metalorganic precursor source.

Reactive and carrier gases are supplied from the chemical delivery system through supply lines into a gas mixing box where they are mixed together and delivered to respective showerheads 1204 and 1104. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

The chamber hybrid MOCVD 302 includes a chamber body 312 that encloses a processing volume 1208. A showerhead assembly 1204 is disposed at one end of the processing volume 1208, and a carrier plate 512 is disposed at the other end of the processing volume 1208. The carrier plate 512 may be disposed on the substrate support 1214.

A lower dome 1219 is disposed at one end of a lower volume 1210, and the carrier plate 512 is disposed at the other end of the lower volume 1210. The carrier plate 512 is shown in process position, but may be moved to a lower position where, for example, the substrates 1240 may be loaded or unloaded. An exhaust ring 1220 may be disposed around the periphery of the carrier plate 512 to help prevent deposition from occurring in the lower volume 1210 and also help direct exhaust gases from the hybrid MOCVD chamber 302 to exhaust ports 1209. The lower dome 1219 may be made of transparent material, such as high-purity quartz, to allow light to pass through for radiant heating of the substrates 1240. The radiant heating may be provided by a plurality of inner lamps 1221A and outer lamps 1221B disposed below the lower dome 1219 and reflectors 1266 may be used to help control the hybrid MOCVD chamber 302 exposure to the radiant energy provided by inner and outer lamps 1221A, 1221B. Additional rings of lamps may also be used for finer temperature control of the substrates 1240.

A purge gas (e.g., nitrogen) may be delivered into the hybrid MOCVD chamber 302 from the showerhead assembly 1204 and/or from inlet ports or tubes (not shown) disposed below the carrier plate 512 and near the bottom of the chamber body 312. The purge gas enters the lower volume 1210 of the hybrid MOCVD chamber 302 and flows upwards past the carrier plate 512 and exhaust ring 1220 and into multiple exhaust ports 1209 which are disposed around an annular exhaust channel 1205. An exhaust conduit 1206 connects the annular exhaust channel 1205 to a vacuum system 1212 which includes a vacuum pump (not shown). The hybrid MOCVD chamber 302 pressure may be controlled using a valve system 1207 which controls the rate at which the exhaust gases are drawn from the annular exhaust channel 1205.

FIG. 3 is a schematic view of a hybrid HVPE apparatus 700 which may be utilized, in accordance with embodiments of the present invention. The hybrid HVPE apparatus 700 includes a hybrid HVPE chamber 702 enclosed by a lid 704. To perform CVD with non-metalorganic precursors for silicon-based diode layer growth, the hybrid HVPE apparatus 700 includes a silicon precursor delivery system 711 coupled to a silicon source deliverable through a gas distribution showerhead 706. An alloy source (e.g., germanium source) may be further included for growth of a transition/buffer layer, if desired.

As further depicted, the hybrid HVPE chamber 702 may also receive a processing gas from a first gas source 710 via the gas distribution showerhead 706. In one embodiment, the first gas source 710 may comprise a nitrogen containing compound and/or silicon containing compound. In another embodiment, the first gas source 710 may comprise ammonia. In one embodiment, an inert gas such as helium or diatomic nitrogen may be introduced as well either through the gas distribution showerhead 706 or through the walls 708 of the hybrid HVPE chamber 702. In further embodiments, the first gas source 710 is configured to provide oxidizers, such as O₂, ozone, etc., to facilitate deposition of silicon-containing non-crystalline compounds (e.g., SiO₂, Si3N₄). In certain such embodiments, the precursor delivery system 711 provides silica precursors (e.g., TEOS or others known in the art) to the hybrid HVPE chamber 702. An energy source 712 may be disposed between the first gas source 710 and the gas distribution showerhead 706. In one embodiment, the energy source 712 may comprise a heater. The energy source 712 may break up the gas from the first gas source 710, such as ammonia, so that the nitrogen from the nitrogen containing gas is more reactive.

To react with the gas from the first gas source 710, precursor material may be delivered from one or more second sources 718. The precursor may be delivered to the hybrid HVPE chamber 702 by flowing a reactive gas over and/or through the precursor in the precursor source 718. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 732 and be heated with the resistive heater 720. By increasing the residence time of the chlorine containing gas, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 720 within the second chamber 732 in a boat. The chloride reaction product may then be delivered to the hybrid HVPE chamber 702. The reactive chloride product first enters a tube 722 where it evenly distributes within the tube 722. The tube 722 is connected to another tube 724. The chloride reaction product enters the second tube 724 after it has been evenly distributed within the first tube 722. The chloride reaction product then enters into the hybrid HVPE chamber 702 where it mixes with the nitrogen containing gas to form a nitride layer on the substrate 716 that is disposed on a susceptor 714 above a lower lamp heating module 728. The other reaction products, such as nitrogen and chlorine, are exhausted through an exhaust 726.

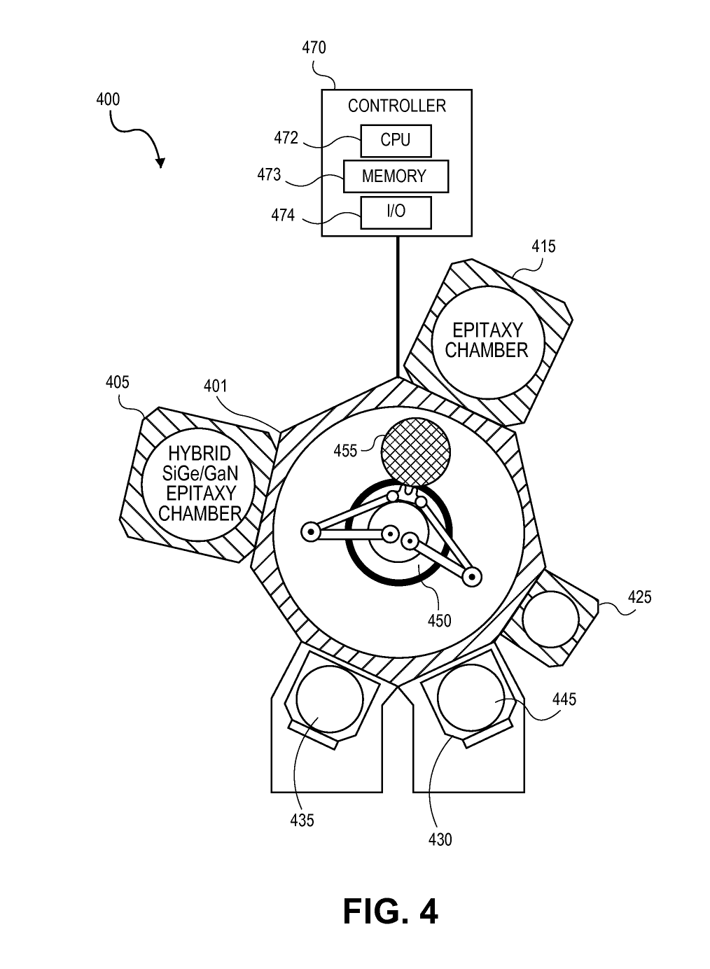

In a further embodiment, at least one hybrid epitaxy chamber, such as the hybrid MOCVD and HVPE chamber depicted in FIGS. 2 and 3, respectively, is coupled to a platform to form a multi-chambered epitaxy system. As shown in FIG. 4, the multi-chambered processing platform 400 may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif. Alternatively, in-line deposition platforms may be utilized. The exemplary multi-chambered processing platform 400 further includes load lock chambers 430 and holding cassettes 435 and 445, coupled to the transfer chamber 401 including a robotic handler 450.

Embodiments of the present invention further include an integrated metrology (IM) chamber 425 as a component of the multi-chambered processing platform 400. The IM chamber 425 may provide control signals to allow adaptive control of integrated deposition process, such as the multiple segmented epitaxial growth method 100. Integrated metrology may be utilized as the substrate is transferred between epitaxy chambers. The IM chamber 425 may include any metrology described elsewhere herein to measure various film properties, such as thickness, roughness, composition, and may further be capable of characterizing grating parameters such as critical dimensions (CD), sidewall angle (SWA), feature height (HT) under vacuum in an automated manner. Examples include, but are not limited to, optical techniques like reflectometry and scatterometry. In particularly advantageous embodiments, in-vacuo optical CD (OCD) techniques are employed where the attributes of a grating formed in a starting material are monitored as the epitaxial growth proceeds.

Where the silicon-based diode layers and/or the GaN-based LED layers are formed with interruption (i.e., ex-situ), a dedicated epitaxy chamber 415, configured for either silicon-based films or GaN-based films alone, may be utilized to grow either one of a doped silicon layer of a silicon-based diode stack or a GaN layer of a GaN-based LED stack with the substrate 455 transferred between successive growth operations. As such, the hybrid epitaxy chamber 405 or dedicated epitaxy chamber 415 may perform the particular group III-nitride growth operations described elsewhere herein.

In one embodiment of the present invention, adaptive control of the multi-chambered processing platform 400 is provided by a controller 470. The controller 470 may be one of any form of general-purpose data processing system that can be used in an industrial setting for controlling the various subprocessors and subcontrollers. Generally, the controller 470 includes a central processing unit (CPU) 472 in communication with a memory 473 and an input/output (I/O) circuitry 474, among other common components. Software commands executed by the CPU 472, cause the multi-chambered processing platform 400 to, for example, load a substrate into the first hybrid epitaxy chamber 405, execute one or more of a first doped silicon film growth process and a GaN growth process, with or without interruption.

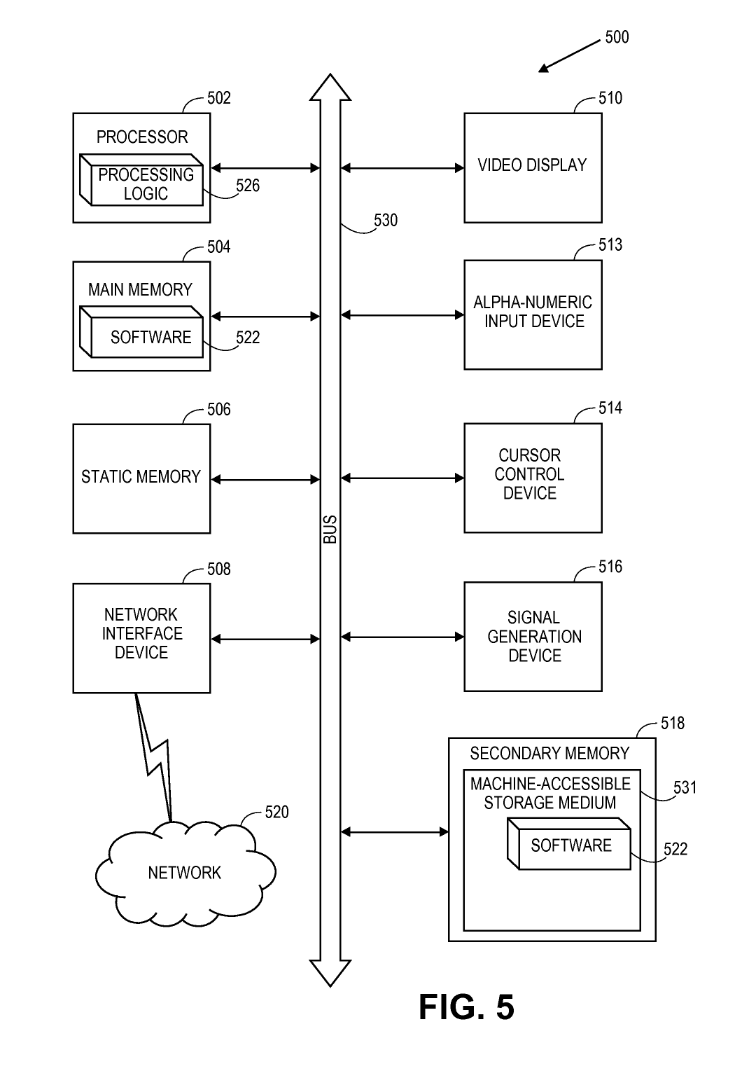

FIG. 5 illustrates a diagrammatic representation of a machine in the exemplary form of a computer system 500 which may be utilized to control one or more of the operations, process chambers or multi-chambered processing platforms described herein. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC) capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the process operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methods or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

The machine-accessible storage medium 531 may further be used to store a set of instructions for execution by a processing system and that cause the system to perform any one or more of the embodiments of the present invention. Embodiments of the present invention may further be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, and flash memory devices, and other similarly well-known non-transitory media).

It is to be understood that the above description is intended to be illustrative, and not restrictive. Many other embodiments will be apparent to those of skill in the art upon reading and understanding the above description. For example, where the exemplary embodiments are described in terms of an GaN LED stack, a zener diode may be formed a part of a transition layer in other device stacks. In one embodiment, a zener diode is formed as a part of a transition layer which includes SiC in a GaN HEMT and/or power transistor stack having an n-type GaN layer disposed on a silicon substrate. First layers of a such a transition layer may include p-type and n-type silicon with a SiC buffer layer disposed over the doped silicon layers.

In still other embodiments, the exemplary GaN LED stack formed over a monocrystalline zener diode embedded in a transition layer between a GaN material system and a silicon substrate may be alternately implemented with the zener diode on the top side of a GaN LED stack formed on any substrate, silicon or otherwise (e.g., sapphire). For a topside zener diode implementation, the zener diode may be made in polycrystalline silicon-based layers formed on the GaN LED stack. The n-type and p-type silicon-based layers may be formed in-situ with one or more GaN-based materials of the GaN LED stack substantially as described for the exemplary transition layer embodiments described herein.

Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A method for fabricating a monolithic ESD protected GaN-based device, the method comprising:
forming a diode material stack with a doped silicon-containing layer deposited over a silicon substrate;
forming a GaN-based device stack over the doped silicon-containing layer; and
electrically connecting the diode material stack with the GaN-based device stack to provide ESD protection to the GaN-based device.

2. The method as in claim 1, further comprising forming a silicon-containing transition layer over the doped silicon-containing layer and wherein the GaN-based device stack is grown over the silicon alloy transition layer.

3. The method as in claim 1, wherein the silicon substrate has a first conductivity type and wherein forming the diode material stack further comprises growing a first silicon layer of a second conductivity type, complementary to the first conductivity type; and
wherein electrically connecting the diode material stack with the GaN-based devicee stack further comprises forming a metal interconnect between the first silicon layer and an electrode of a GaN-based LED.

4. The method as in claim 1, wherein the silicon substrate has a first conductivity type and wherein forming the diode material stack further comprises growing a first silicon layer of a second conductivity type, complementary to the first conductivity type;
wherein forming the diode material stack further comprises forming a second silicon layer disposed over the first silicon layer, the second silicon layer being of the first conductivity type to form a second diode as part of the diode material stack; and
wherein electrically connecting the diode material stack with the GaN-based device stack further comprises forming a metal interconnect between the second silicon layer and an electrode on a GaN-based LED material stack.

5. The method as in claim 3, wherein the first conductivity type is n-type and wherein the first silicon layer is electrically connected to an n-type layer of the GaN-based device stack.

6. The method as in claim 4, wherein the first conductivity type is n-type and wherein the second silicon layer is electrically connected to an n-type layer of the GaN-based LED material stack to form an anode-to-anode connected Zener diode pair.

7. The method as in claim 4, wherein the first conductivity type is p-type and wherein the second silicon layer is electrically connected to an n-type layer of the GaN-based LED material stack to form a cathode-to-cathode connected Zener diode pair configured in parallel with the GaN-based LED.

8. The method as in claim 2, wherein forming the silicon containing transition layer comprises epitaxially growing a silicon alloy including at least one of germanium(Ge), carbon (C), and tin (Sn), over the silicon substrate.

9. A system for fabricating a monolithic ESD protected GaN-based device, the system comprising:
a first precursor delivery system configured to be coupled to a silicon precursor;
a second precursor delivery system configured to be coupled to a metalorganic precursor; and
one or more deposition chambers coupled to the first and second precursor delivery systems to form a ESD protection diode material stack including a doped silicon-containing layer and to form a GaN-based device stack disposed over the doped silicon-containing layer.

10. The system as in claim 9, wherein the one or more deposition chamber comprises a hybrid metalorganic chemical vapor deposition (MOCVD) chamber configured to perform silicon CVD or a hybrid hydride/halide vapor phase epitaxy (HVPE) chamber configured to perform silicon CVD.

11. The system as in claim 9, wherein the first precursor delivery system is configured to provide the silicon precursor to the hybrid deposition chamber concurrently with a p-type or n-type dopant source.

12. The system as in claim 9, further comprising:
a transfer module coupled to the hybrid deposition chamber;
a first deposition chamber configured for silicon CVD; and
a second deposition chamber configured for GaN epitaxy, wherein each of the first and second deposition chambers are also coupled to the transfer module.

13. A monolithic ESD protected GaN-based LED, comprising:
diode material stack with a doped silicon-containing layer deposited over a silicon substrate;
a GaN-based LED material stack disposed over the doped silicon-containing layer and electrically connected with the diode material stack to provide ESD protection to the GaN-based LED.

14. The monolithic ESD protected GaN-based LED of claim 13, further comprising a silicon containing transition layer over the doped silicon-containing layer, and wherein the GaN-based LED material stack is disposed directly on the silicon containing transition layer.

15. The monolithic ESD protected GaN-based LED of claim 13, wherein the silicon substrate has a first conductivity type and wherein the diode material stack further comprises a first silicon layer of a second conductivity type, complementary to the first conductivity type; and
wherein the first silicon layer is coupled to an electrode of the GaN-based LED with a metal interconnect.

16. The monolithic ESD protected GaN-based LED of claim 13, wherein the silicon substrate has a first conductivity type and wherein the diode material stack further comprises a first silicon layer of a second conductivity type, complementary to the first conductivity type;
wherein the diode material stack further comprises a second silicon layer disposed over the first silicon layer, the second silicon layer being of the first conductivity type to form a second diode as part of the diode material stack; and
wherein the second silicon layer is coupled to an electrode of the GaN-based LED material stack with a metal interconnect.

17. The monolithic ESD protected GaN-based LED of claim 15, wherein the first conductivity type is n-type and wherein the first silicon layer is electrically connected to an n-type layer of the GaN-based LED material stack.

18. The monolithic ESD protected GaN-based LED of claim 16, wherein the first conductivity type is n-type and wherein the second silicon layer is electrically connected to an n-type layer of the GaN-based LED material stack to form an anode-to-anode connected Zener diode pair.

19. The monolithic ESD protected GaN-based LED of claim 4, wherein the first conductivity type is p-type and wherein the second silicon layer is electrically connected to an n-type layer of the GaN-based LED material stack to form a cathode-to-cathode connected Zener diode pair configured in parallel with the GaN-based LED.

20. A computer-readable medium having stored thereon a set of instructions which when executed cause a system to perform the method of claim 1.
